(19) United States
(12) Patent Application Publication
(10) Pub. No.: US 2015/0200667 A1
(43) Pub. Date: Jul. 16, 2015

(54) COLLAPSIBLE GLUE LOGIC SYSTEMS AND METHODS

(71) Applicant: QUALCOMM Incorporated, San Diego, CA (US)

(72) Inventors: Shiva Ram Chandrasekaran, San Diego, CA (US); Chandrasekhar Reddy Singasani, San Jose, CA (US); Joey Dacanay, San Diego, CA (US); Mamta Bansal, San Diego, CA (US); Arman Ohanian, San Diego, CA (US); Satish Raj, San Diego, CA (US); Kiran Srinivasa Sastry, San Diego, CA (US); Abhirami Senthilkumaran, San Diego, CA (US); Tarek Zghal, San Diego, CA (US); Parissa Najdesamii, San Diego, CA (US); Sunil Kumar, San Diego, CA (US)

(73) Assignee: QUALCOMM Incorporated, San Diego, CA (US)

(21) Appl. No.: 14/155,734

(22) Filed: Jan. 15, 2014

(51) Int. Cl. H03K 19/00; G06F 1/32

(52) U.S. Cl. CPC H03K 19/0008; G06F 1/3287

(57) ABSTRACT

Provided are systems and methods for reducing power consumption in the interface and routing circuitry associated with various core modules of an integrated circuit or system. One system includes core modules, glue logic domains adapted to interface the plurality of core modules, and a power controller electrically coupled to the glue logic domains. Each glue logic domain includes a glue logic module implemented as a soft macro with metal traces extending beyond an extent of the glue logic module. The power controller decouples power from selected glue logic domains based on control signals and/or detected power down states of core modules and/or other glue logic domains. The power controller facilitates the power transitions using logic state retention, logic state clamping, ordered or scheduled transitioning, and/or other power transition systems and methods.

### FIELD OF THE INVENTION

The present disclosure generally relates to reducing power consumption in electronic devices and more particularly to systems and methods for reducing power consumption in the interface and routing circuitry associated with various core modules of an integrated circuit or system of integrated circuits.

### BACKGROUND

Conventional electronic device design is often dictated by power use, particularly in the realm of portable, battery-operated electronic devices. To address this, and to take advantage of smaller semiconductor process dimensions, more and more functionality has been integrated into a single package of multiple integrated circuits (ICs), or even a single IC, because a single package or single IC can be powered more efficiently. This has resulted in the development of system in package (SIP) and system on chip (SOC) electronic devices, and their operation is typically a balance between performance and power dissipation concerns.

SOCs are typically designed according to a strict hierarchy. Relatively large and/or complex structures such as function-specific modules, microprocessor cores, and other core modules, are often designed separately and characterized according to a time intensive pre-validation process. These structures are denoted as “hard macros.” It is common to place a number of hard macros onto a die, but hard macros require glue logic to accommodate the routing of signals to and from each hard macro. In contrast to hard macro core modules, glue logic is typically implemented as one or more “soft macros” that are not designed and tested separately.

The design process difference between hard macros and soft macros leads to a physical difference between them. In general, both a soft macro and a hard macro have corresponding footprints on the die. The footprint refers to the semiconductor substrate surface area dedicated to the various transistors and other devices that constitute a given module or circuit (e.g., a soft or hard macro). As known in the semiconductor arts, a plurality of metal layers are deposited on the semiconductor substrate and thus over the footprints of the various modules. These metal layers support the signaling between transistors and the other devices on the die. For example, the metal layers may form traces or leads that interconnect one logic device to another. It is these metal layer leads that provide one physical distinction between hard macros and soft macros.

Because of the separate design and testing of a hard macro, the metal layer leads that interconnect its devices (e.g., logic gates, and/or other semiconductor devices) are confined to the space above the corresponding footprint on the die. This is not the case for a soft macro: a soft macro's devices may be interconnected by metal layer traces that travel outside the soft macro's footprint and then travel back inside the footprint as they interconnect one device to another. This physical distinction is shown in FIG. 8A for an IC 800. A hard macro is represented by its footprint 805. The logic gates for hard macro 805 are interconnected by metal layer traces 810 that stay within the metal layer space above footprint 805. In other words, the signaling between its devices (e.g., logic gates) does not traverse outside of the boundaries for footprint 805. Note that other metal layer traces (not illustrated) would of course traverse the boundaries of footprint 805 to connect the hard macro to other modules 825 (e.g., soft and hard macros) on IC 800. By contrast, a soft macro represented by its footprint 815 includes devices that are interconnected by metal layer traces 820 that may traverse across the boundaries of footprint 815.

These design distinctions between hard macros and soft macros leads to a power distribution and/or consumption issue. Typically, hard macros include their own power management logic and other devices. In particular, because the hard macros are designed separately, they are powered by their own local power rail and thus may be readily shut down when not needed to prolong battery life. An example SOC 850 is shown in FIG. 8B that includes a plurality of hard macro cores or modules 855. As discussed previously, hard macro cores 855 would thus be designed and tested separately from remaining components in SOC 850. It is thus convenient to interface hard macro cores 855 with soft macro glue logic 860. Glue logic 860 includes an interface 865 to each hard macro core 855 as well as routing logic 870 to accommodate the routing of signals between hard macro cores 855. Because glue logic 860 is designed as one or more soft macros, it is conventional for it to be non-collapsible (e.g., to remain powered on) despite the collapse (power down) of various ones of hard macro cores 855. This is quite inefficient because there is substantial power dissipation in the circuitry and/or switching activity of interfaces 865 and routing logic 870 despite the collapse of various hard macro cores 855. To avoid the unnecessary power dissipation in non-collapsible glue logic, the glue logic may be implemented using a set of relatively large hard macros. This method is typically undesirable, however, because there is still a need for custom logic and other circuitry to then interface the glue logic hard macros in any SOC design.

Thus, there is a need in the art for selectively collapsible glue logic systems and methods that reduce power usage in a constituent electronic device without substantially degrading overall performance.

### SUMMARY

Provided are systems and methods for reducing power consumption in the interface and routing circuitry associated with various core modules of an integrated circuit (IC) or system of integrated circuits. One system includes one or more core modules, a glue logic matrix electrically coupled to the core modules, and a power controller electrically coupled to a portion of the glue logic matrix (a glue logic domain) that corresponds to one or more of the core modules. The power controller is adapted to couple and decouple the glue logic domain from a power source based on signals provided to the power controller and/or power down states of core modules and/or other glue logic domains. The power controller is also adapted to facilitate the power transitions of the glue logic domain using a variety of systems and methods, such as logic state retention, logic state clamping, ordered or scheduled transitioning, and/or other power transition systems and methods.

In one embodiment, an electronic device includes a plurality of core modules, each core module being configured to have a power-on state and a power-off state; a plurality of glue logic domains corresponding to the plurality of core modules, wherein each glue logic domain is adapted to interface its corresponding core module to remaining ones of the core modules, and wherein each glue logic domain is implemented as one or more soft macros; and a power controller adapted to control a power state for each glue logic domain, wherein the power controller is adapted to command a power-off state for each glue logic domain corresponding to a core module in the power off state.

In another embodiment, a method for controlling power to glue logic disposed within a glue logic domain includes receiving a power down signal to power down the glue logic domain; clamping one or more outputs of the glue logic disposed within the glue logic domain; and decoupling the glue logic from a power source for the glue logic domain.

In another embodiment, a method for controlling power to glue logic disposed within a monitored glue logic domain includes detecting a power down state of a core module or an external glue logic domain associated with the monitored glue logic domain; clamping one or more outputs of the glue logic disposed within the monitored glue logic domain; and decoupling the glue logic from a power source for the monitored glue logic domain.

In a further embodiment, a method for determining a layout for an IC comprising collapsible glue logic includes receiving a net list for the layout; determining one or more glue logic domains for the collapsible glue logic listed in the net list; determining a power grid placement based, at least in part, on the glue logic domains; determining a further device placement based, at least in part, on the glue logic domains and the power grid placement; and determining a detailed circuit routing between the further devices based on the net list and the determined placements.

The claims listed below are incorporated into this section by reference. The above and other features and advantages of the present disclosure will be more readily apparent from the detailed description of the embodiments set forth below taken in conjunction with the accompanying drawings.

### BRIEF DESCRIPTION OF THE FIGURES

The various figures and text attached herein illustrate various processes, devices, and systems for implementing one or more electronic smoking devices and/or assemblies, processes to make, sell and/or use such devices and/or assemblies, and/or systems embodying such processes, devices, and/or assemblies, for example, in accordance with embodiments of the disclosure.

FIG. 1 is a block diagram of an electronic device with multiple glue logic domains in accordance with an embodiment of the disclosure.

FIG. 2 is a block diagram of an electronic device with a glue logic domain in accordance with an embodiment of the disclosure.

FIG. 3 is a block diagram of a global distributed head switch system for a glue logic domain in accordance with an embodiment of the disclosure.

FIG. 4 is a block diagram of a clamp system for a glue logic domain in accordance with an embodiment of the disclosure.

FIG. 5 is a flowchart illustrating a method for controlling power to glue logic disposed within a glue logic domain in accordance with embodiments of the disclosure.

FIG. 6 is a flowchart illustrating a method for controlling power to glue logic disposed within a monitored glue logic domain in accordance with embodiments of the disclosure.

FIG. 7 is a flowchart illustrating a method for determining a layout for an IC comprising collapsible glue logic in accordance with embodiments of the disclosure.

FIG. 8A illustrates the metal layer routing for a hard macro module and a soft macro module in a conventional die.

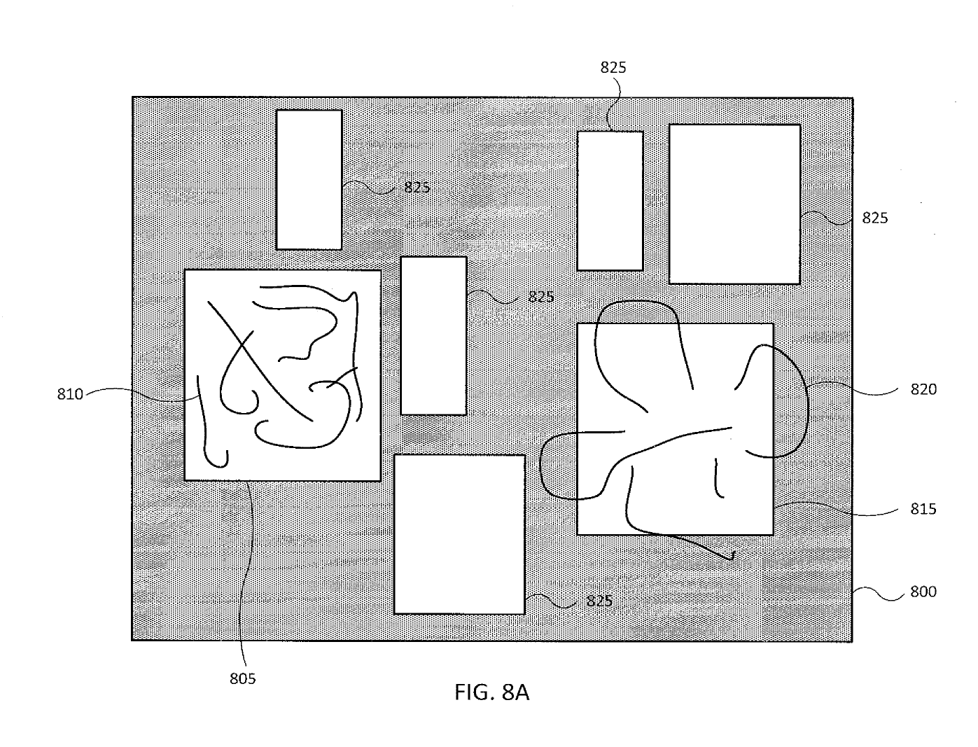

FIG. 8B illustrates a conventional die including a plurality of hard macro cores coupled together through non-collapsible glue logic.

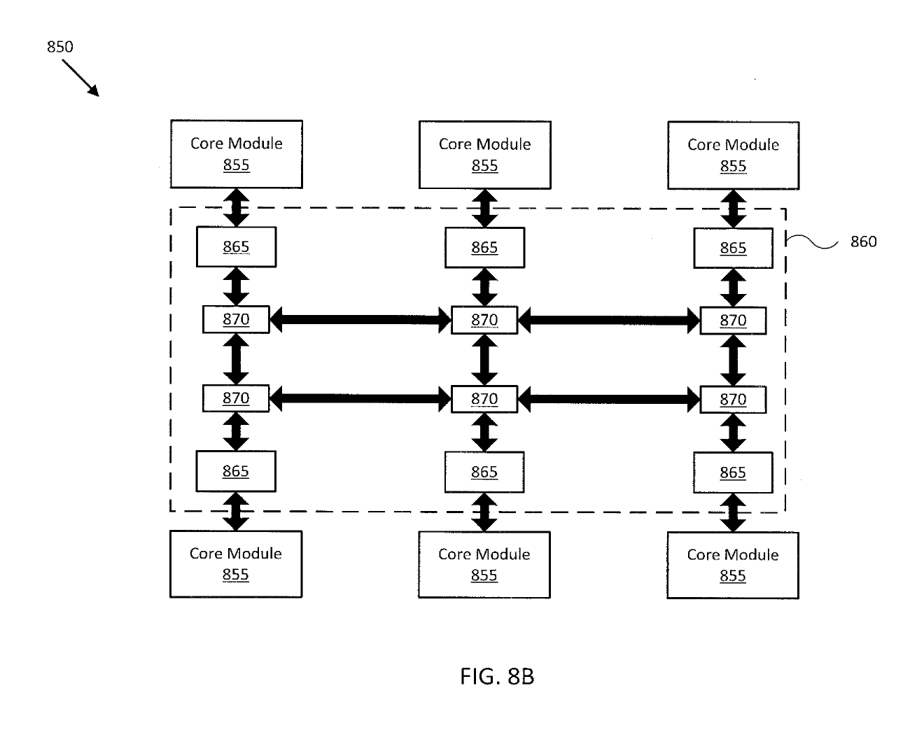

Embodiments of the present disclosure and their advantages are best understood by referring to the detailed description that follows. It should be appreciated that like reference numerals are used to identify like elements illustrated in one or more of the figures, wherein showings therein are for purposes of illustrating embodiments of the present disclosure and not for purposes of limiting the same.

### DETAILED DESCRIPTION

To provide more efficient power savings for a system including a plurality of independently-collapsible hard macro cores or modules, a plurality of collapsible soft macro glue logic domains is provided corresponding to the plurality of hard macro cores. In this fashion, each glue logic domain corresponds to one or more cores such that each glue logic domain is configured to accommodate the interfacing of the corresponding core to remaining ones of the cores. More generally, among the hard macro cores, some of the cores may be in a master/slave relationship with each other. In such an embodiment, the corresponding glue logic domain may accommodate the interfacing for both a master core and any of its slaves. It will thus be appreciated that the cores may be divided into independently-controlled sets. A set may have just a single core as a member if it is not in a master-slave relationship with other ones of the cores. Alternatively, a set corresponding to a core in a master-slave relationship with other cores would include the remaining cores in that master-slave relationship. Each set thus has a corresponding glue logic domain to accommodate the interfacing of that set to remaining ones of the cores.

A power controller is configured to monitor whether each core is collapsed (powered off) or powered on so as to command a power state for the corresponding glue logic domains accordingly. In other words, the power controller powers off those glue logic domains corresponding to collapsed cores. If a core is powered on, the power controller maintains the corresponding glue logic domain in a power-on state accordingly. The resulting control by the power controller is quite advantageous because of the additional power savings of turning off those glue logic domains corresponding to collapsed cores. Moreover, this power savings is achieved despite the implementation of the glue logic domains as soft macros, which eases the design complications considerably. These advantageous features may be better appreciated with regard to the following discussion of some example embodiments.

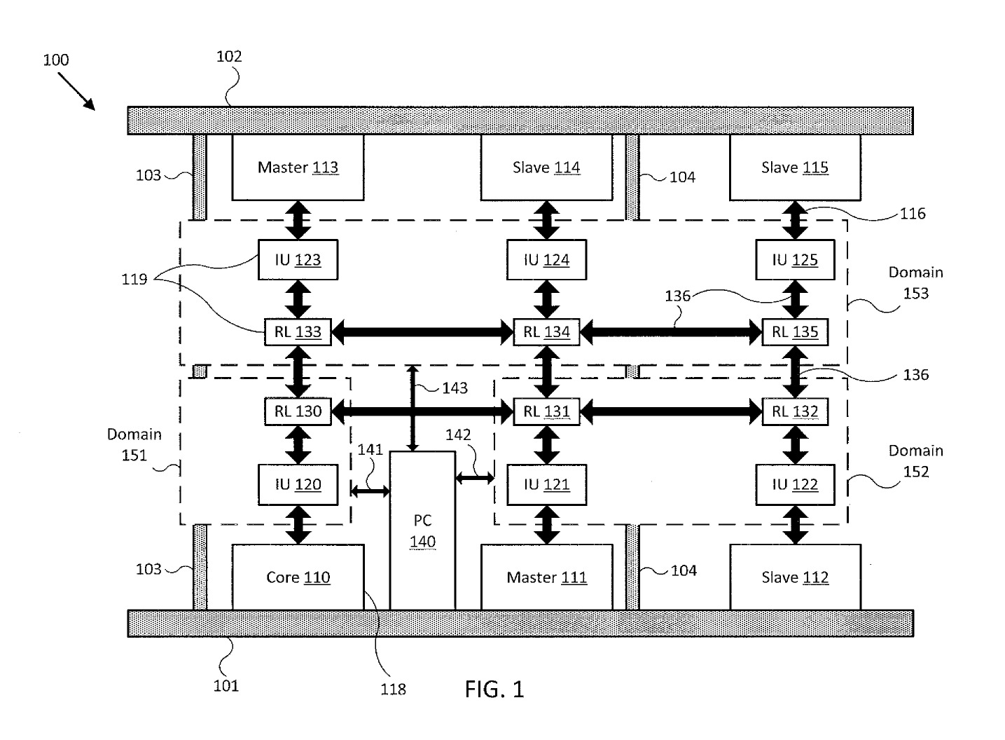

Turning now to the drawings, FIG. 1 is a block diagram of an electronic device 100 including a plurality of soft macro glue logic domains 151, 152, and 153 in accordance with an embodiment of the disclosure. Glue logic domain 153 is configured to accommodate the interfacing of a set of hard macro cores or modules, including a master core 133 and two slave cores 114 and 115. Similarly, glue logic domain 152 is configured to accommodate the interfacing for a master core 111 and a slave core 112. But core 110 comprises a set of just one since it is operated independently of all the remaining cores. Glue logic domain 151 is thus configured to accommodate the interfacing for core 110 alone. Similarly, other independent cores (not illustrated) on device 100 would interface through corresponding glue logic domains (not illustrated). Each glue logic domain includes an interface unit for each of the cores within the corresponding set. For example, glue logic domain 153 includes an interface unit 132 that accommodates the interfacing to master core 113. Glue logic domain 153 also includes interface units 124 and 125 for interfacing to slave cores 114 and 115, respectively.

Similarly, glue logic domain 152 includes interface units 121 and 122 for interfacing to master core 111 and slave core 112, respectively. Finally, glue logic domain 151 includes an interface unit 120 for interfacing to core 110. The signaling between the various interface units is accommodated by routing logic modules 130-135 such as switch fabrics. Each interface unit (IU) couples to its corresponding core over a bus 116. Similarly busses such as busses 136 couple between the routing logic modules and between the interface units and the routing logic modules (RLs). Glue logic domains 151-153 may be collectively referred to as a glue matrix.

Glue logic domains 151-153 delineate portions of the glue matrix that are subject to similar power down/up states during normal operation of electronic device 100. For example, in embodiments where master 113 controls operation of slaves 114 and 115, a power down state of master 113 may force a power down state of slave 114 and 115. If all three core modules are in a power down state, interface units 123-125 and routing logic modules 133-135 in glue logic domain 153 may also be powered down without degrading the performance of remaining core modules 110-112. Thus, glue logic domain 153 may be decoupled from a power source without negatively impacting the operation of powered cores in device 100.

Power sources for electronic device 100 may be implemented as one or more metal and/or conductive power rails, such as power rails 101-104. For example, in some embodiments, electronic device 100 may be implemented as a system on chip (SOC). When implemented as an SOC, power rails 101-104 may be formed as leads in one or more metal layers overlaying the substrate in which device 100. As shown in FIG. 1, rails 101-104 have varying widths substantially dictated by a total power rating for the devices powered by each rail. As shown in FIG. 1, power rails 101 and 102 are relatively wide and provide power to core modules 110-115 and relatively narrow power rails 103 and 104. Glue logic domain 151 receives power from power rail 103, and glue logic domain 152 receives power from power rail 104. Glue logic domain 153 can receive power from power rail 103 and/or 104.

A power controller 140 controls the power on or power off state for the glue logic domains as discussed above. As shown, power controller 140 receives power from power rail 101 and controls glue logic domain 151-153 through respective buses 141-143. Busses 141-143 may be implemented as two-way buses to facilitate control and communication with other modules of electronic device 100, as described more fully within. For example, power controller 140 may be adapted to couple or decouple glue logic domains 151-153 from their respective power source(s), and/or to clamp or de-clamp outputs of glue logic within glue logic domains 151-153. Power controller 140 may be adapted to detect power states of various modules and/or glue logic domains of electronic device 100 based on communications with modules within each of glue logic domains 151-152, For example, power controller 140 may be adapted to communicate (e.g., send and receive signals) with core 110 through interface unit 120 using busses 141 and 116. In some embodiments, power controller 140 may be adapted to provide power over buses 141-143 to select components within respective glue logic domains 151-153.

Each of hard macro core modules 110-115, soft macro glue logic domains 150-153, and power controller 140 may be implemented as one or more logic devices, semiconductor structures, and/or other semiconductor devices with metal traces interconnecting the semiconductor devices of each component. For example, each of core modules 110-115, IUs 120-125, RLs 130-135, and power controller 140 may comprise one or more microcontrollers, microprocessors, field programmable gate arrays (FPGAs), semiconductor-based memory structures, multiplexors, amplifiers, transistors, and/or other IC structures. Power controller 140 may be implemented as a hard or soft macro, and in some embodiments, be implemented as a number of interconnected power controllers 140 distributed across IC 100 and acting in conjunction to control power states of each of glue logic domains 151-153. Buses 116, 136, and 141-143 may be implemented as signal buses interconnecting the various modules of IC 100, and may each include multiple metal traces and/or patterns adapted to conduct signals (e.g., data signals, control signals, power, and/or other signals) between the various modules of IC 100.

As noted earlier, hard macros such as core modules 110-115 are structurally distinct from soft macros such as glue logic domains 151-153. In particular, these structures are represented in FIG. 1 as by their footprints on a substrate surface (not illustrated). The boundary of a footprint for a hard macro may be implemented as a guard ring such as a guard ring 118 for core module 110. In some embodiments, a guard ring may include one or more layers of insulating dielectric material physically and electrically isolating a corresponding module from other modules and/or metal traces of IC 100. In other embodiments, a guard ring may include one or more substantially concentric layers of dielectric materials and/or metal (e,g. conductive) materials separated by dielectric layers to provide isolation from electromagnetic signals caused by other modules and/or metal traces of IC 100. Modules implemented as soft macros, such as IUs 120-125 and/or RLs 130-135 do not include a physical and/or electrical separation structure disposed along their boundaries 119.

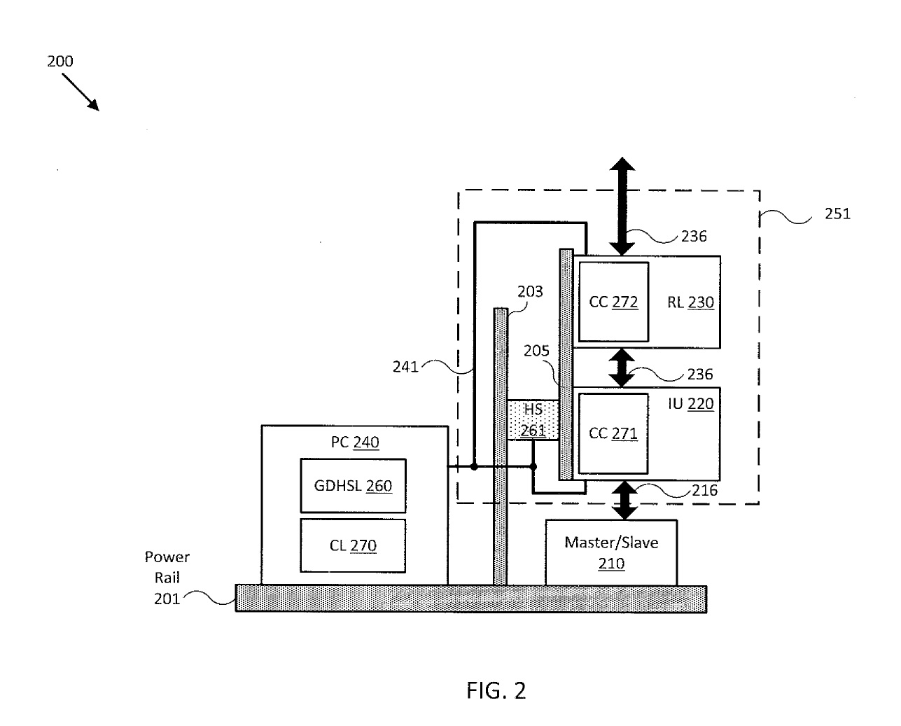

To better illustrate the advantageous control of the glue logic domains, a glue logic domain 251 is shown in more detail in FIG. 2 for an electronic device 200 in accordance with an embodiment of the disclosure. As shown, power controller 240 includes global distributed head switch logic (GDHSL) 260 and clamp logic (CL) 270. Glue logic domain 251 includes head switch 261 disposed between power rail 203 and intra-domain power rail 205, where head switch 261 is controlled by GDHSL 260. Interface unit 220 and routing logic module 230 include respective clamp cells 271 and 272 controlled by CL 270. The remaining elements are implemented similarly to those similarly enumerated in FIG. 1.

Head switch 261 may be adapted to couple and decouple power rail 203 from inter-domain power rail 205 (which in turn powers interface unit 220 and routing logic module 230) based on signals provided by GDHSL 260. Clamp cells 271 and 272 may be adapted to clamp outputs of interface unit 220 and/or 230 (e.g., buses 216 and/or 236) to one or more logic states based on signals provided by CL 270. GDHSL 260 may be adapted to determine a power state for glue logic domain 251 and/or various components within glue logic domain 251 based on signals received from core module 210 and/or other core modules, detected power states of core module 210, other core modules, or other glue logic domains, and/or other signals provided to power controller 240 or from CL 270. CL 270 may be adapted to retrieve and store a logic state of outputs of interface unit 220 and/or routing logic 230, to clamp those outputs to the retrieved logic state or a known logic state (e.g., all null, or another pattern of logic states), and to determine other clamp cell characteristics based on signals provided to power controller 240 or from GDHSL 260. GDHSL 260 and CL 270 may each be implemented as one or more of the logic devices, semiconductor structures, and/or other semiconductor devices (and interconnecting metal traces) of power controller 240.

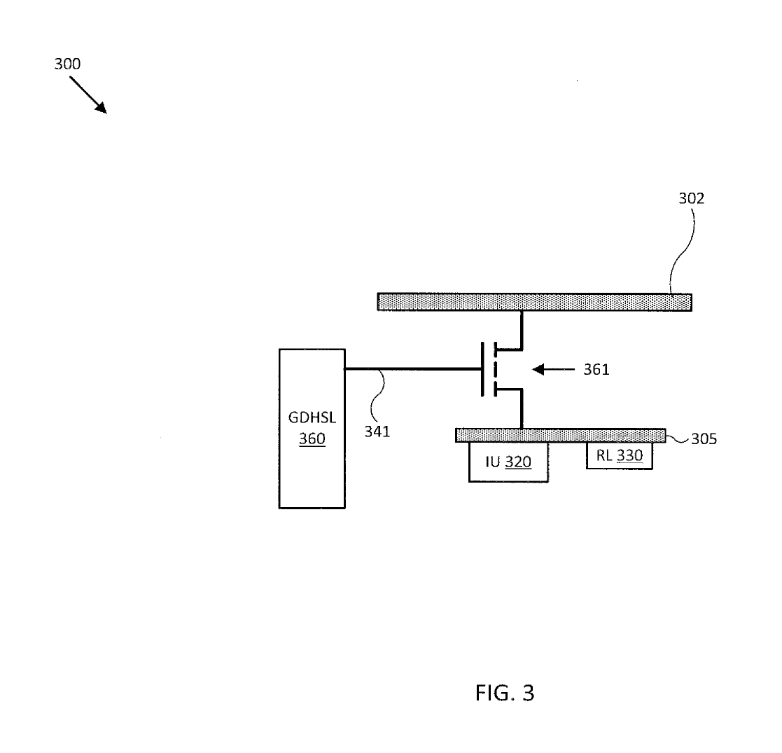

GDHSL 260, bus 241, head switch 261, and power rails 201, 203, and 205 may be implemented in a number of different embodiments and form at least part of a global distributed head switch system for one or more glue logic domains. For example, FIG. 3 is a block diagram of a global distributed head switch system 300 for a glue logic domain (e.g., glue logic domain 151 in FIG. 1 and/or glue logic domain 251 in FIG. 2) in accordance with an embodiment of the disclosure. As shown, system 300 includes GDHSL 360 controlling head switch 361 disposed between power rails 302 and 305. In one embodiment, head switch 361 may be implemented as one or more transistors with gates coupled to GDHSL 360. For example, head switch 361 may be implemented as at least one MOSFET with a junction design and/or insulator material chosen to emphasize low gate leakage over switching speed. In some embodiments, head switch 361 may be implemented as an enhancement mode or a depletion mode MOSFET depending on expected operating statistics for an associated electronic device and/or glue logic domain. For example, if a glue logic domain is only rarely powered down, head switch 361 may be implemented as a depletion mode MOSFET to require no gate voltage to couple power rail 302 to power rail 305. The remaining elements of FIG. 3 are implemented in a similar fashion to those similarly enumerated in FIGS. 1 and 2.

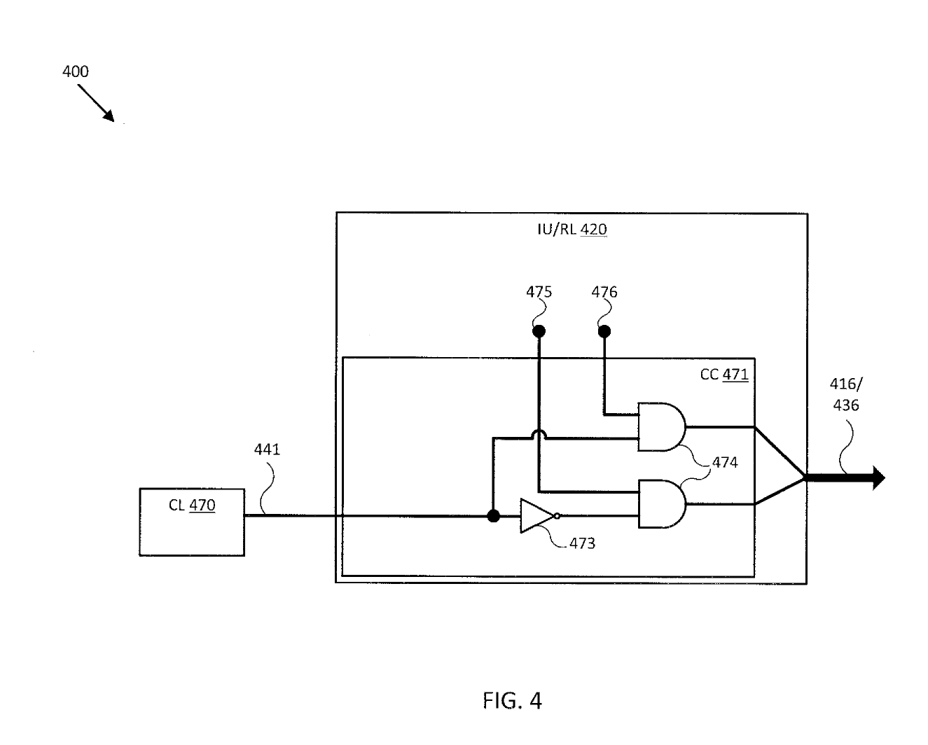

As with global distributed head switch system 300 of FIG. 3, clamp logic 270. bus 241, IU 220, RL230, and/or clamp cells 271 and 272 of FIG. 2 may be implemented in a number of different embodiments and form at least part of a clamp system for one or more glue logic domains. FIG. 4 is a block diagram of a clamp system 400 for a glue logic domain (e.g., glue logic domain 151 in FIG. 1 and/or glue logic domain 251 in FIG. 2) in accordance with an embodiment of the disclosure. As shown, system 400 includes CL 470 coupled to clamp cell 471 of interface unit/routing logic module (IU/RL) 420. Nodes 475-476 represent outputs of IU/RL 420, which are selectively clamped by clamp cell 471 before being provided as outputs on bus 416/436. As shown, clamp cell 471 includes an inverter 473 and two AND gates 474. In one embodiment, clamp cell 471 is adapted to camp the signals provided at nodes 475-476 to a particular logic state. In some embodiments, clamp cell 471 may include additional and/or different logic to sample the logic states at nodes 475-476 and provide the states to CL 470, to provide specific logic states (e.g., selected by CL 470) at each output associated with nodes 475-476, and/or to provide other clamping operations, for example. The remaining elements of FIG. 4 are implemented in a similar fashion to those similarly enumerated in FIGS. 1, 2 and 3.

In various embodiments, collapsible glue logic of an electronic device (e.g., IU/RL 420 of electronic device 100) benefits from clamped outputs in that the clamped outputs provide a known state for the outputs when power is decoupled from the glue logic (e.g., when a glue logic domain is collapsed), while power is decoupled from the glue logic, and when power is coupled to the glue logic (e.g., when powering up from a power down state). Clamping outputs of collapsible glue logic modules eliminates erratic operation of the glue logic caused by undefined logic states (e.g., residual voltages) existing on the metal traces interconnecting core modules and glue logic domains. In some embodiments, clamping outputs of collapsible glue logic modules to a particular state or pattern can communicate a state (e.g., a power down or collapsed state, and/or entry into or exit from a power down state) of a glue logic domain to other glue logic domains and/or core modules.

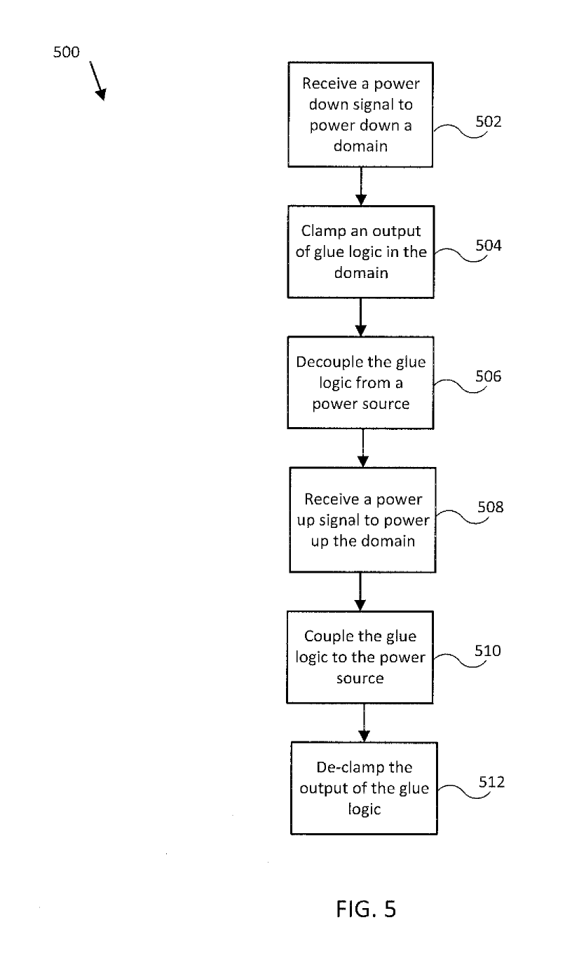

Power controllers for glue logic domains, such as power controller 140 in FIG. 1, may be adapted to control power to one or more glue logic domains according to a variety of methods and/or criteria. For example, FIG. 5 shows a flowchart 500 illustrating a method for controlling power to glue logic disposed within a glue logic domain in accordance with embodiments of the disclosure. In such embodiments, a power controller may be adapted to couple and decouple power to glue logic in a glue logic domain based on one or more power down or power up signals received from a core module. Flowchart 500 is described with reference to the systems, electronic devices, and components described in FIGS. 1-4, but may be implemented with respect to other systems, devices, and components in accordance with the embodiments described herein. Any block, step or sub-step of flowchart 500 may be performed in an order or arrangement different from the specific embodiment illustrated by FIG. 5, and may include fewer, additional, or different steps, in accordance with the embodiments described herein.

At block 502, power controller 140 may receive a power down signal to power down a glue logic domain. For example, power controller 140 may be adapted to receive a power down signal over bus 141 from core module 110 to power down glue logic domain 151. In some embodiments, core module 110 may determine that it is ready to enter a power-off state. Prior to or while entering the power-off state, core module 110 may provide a power down signal to glue logic domain 151 over bus 116 (e.g., to IU 120), which may then be provided to power controller 140 over bus 141. In other embodiments, where bus 141 couples core module 110 directly to power controller 140, the power down signal may be provided directly to power controller 140 over bus 141. In additional embodiments, core module 110 may determine that it may not need to communicate and/or interface with external modules (e.g., using glue logic in glue logic domain 151) for a period of time, for example, and provide a power down signal to glue logic domain 151.

At block 504, power controller 140 may clamp an output of glue logic in glue logic domain 151, in response to receiving a power down signal as described in block 502. For example, clamp logic 441 of FIG. 4 (e.g. of power controller 140 of FIG. 1) may be adapted to provide a logic state to clamp cell 471 of IU/RL 420 over bus 441 corresponding to bus 141 of FIG. 1 and clamp outputs of IU/RL 420 to a particular logic state. In some embodiments, clamp logic 441 and clamp cell 471 may be adapted to store a current logic state of IU/RL 420 prior to clamping its outputs. The outputs may be clamped to the stored logic state, for example, or to a known logic state (e.g., a null logic state) prior to and/or while glue logic domain 151 is powered down. In other embodiments, clamp logic 441 and clamp cell 471 may be adapted to clamp outputs of IU/RL 420 without first storing their current logic state.

At block 506, power controller 140 may decouple IU 120 and/or RL 130 from power rail 103, in response to receiving a power down signal as described in block 502. For example, as shown in FIG. 2, power controller 240 (analogous to power controller 140 in FIG. 1) may be adapted to decouple IU 220 and RL 230 from power rail 203 by providing a control signal to head switch 261 that turns head switch 261 “off” and decouples power rail 203 from intra-domain power rail 205.

At block 508, power controller 140 may receive a power up signal to power up glue logic domain 151. For example, power controller 140 may receive a power up signal over bus 141 from core module 110 to power up glue logic domain 151. In some embodiments, core module 110 may determine that it is ready to enter a power-on state, for example, or may determine that it will need to communicate and/or interface with external modules (e.g., using glue logic in glue logic domain 151) for a period of time. Prior to, while, or after entering the power-on state, core module 110 may provide a power up signal to glue logic domain 151 over bus 116 (e.g., to IU 120), which may then be provided to power controller 140 over bus 141. In other embodiments, where bus 141 couples core module 110 directly to power controller 140, the power up signal may be provided directly to power controller 140 over bus 141.

At block 510, power controller 140 may couple IU 120 and/or RL 130 to power rail 103, in response to receiving a power up signal as described in block 508. For example, as shown in FIG. 2, power controller 240 (analogous to power controller 140 in FIG. 1) may be adapted to couple IU 220 and RL 230 to power rail 203 by providing a control signal to head switch 261 that turns head switch 261 “on” and decouples power rail 203 to intra-domain power rail 205.

At block 512, power controller 140 may de-clamp an output of glue logic in glue logic domain 151, in response to receiving a power up signal as described in block 508. For example, clamp logic 441 of FIG. 4 (e.g. analogous to power controller 140 of FIG. 1) may be adapted to de-clamp outputs of IU/RL 420 and/or provide a previously stored logic state to clamp cell 471 of IU/RL 420, as described herein. Once de-clamped, the outputs of IU/RL 420 may then operate as dictated by operation of IU/RL 420 (e.g., normal operation).

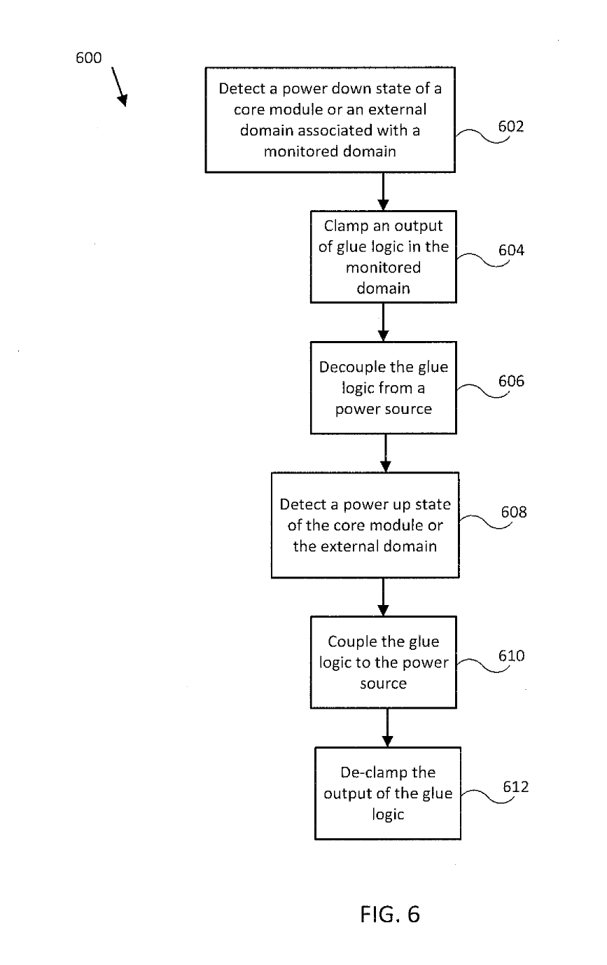

FIG. 6 shows a flowchart 600 illustrating another method for controlling power to glue logic, but where the glue logic is disposed within a monitored glue logic domain in accordance with embodiments of the disclosure. In such embodiments, a power controller may be adapted to detect power down and power up states of core modules and/or external glue logic domains associated with and/or coupled to a monitored glue logic domain. The power controller may be adapted to couple and decouple power to glue logic in the glue logic domain based on the detected power up and down states. Flowchart 600 is described with reference to the systems, electronic devices, and components described in FIGS. 1-4, but may be implemented with respect to other systems, devices, and components in accordance with the embodiments described herein. Any block, step or sub-step of flowchart 600 may be performed in an order or arrangement different from the specific embodiment illustrated by FIG. 6, and may include fewer, additional, or different steps, in accordance with the embodiments described herein.

At block 602, power controller 140 may detect a power down state of a core module and/or an external glue logic domain associated with a monitored glue logic domain. For example, power controller 140 may be adapted to monitor glue logic domain 151 (e.g., making glue logic domain 151 a monitored glue logic domain) and detect a power down state of core module 110 (e.g., the core module associated with glue logic domain 151) or glue logic domains 152 and 153 (e.g., external glue logic domains associated with/adjacent to/coupled to monitored glue logic domain 151). In some embodiments, power controller 140 may be adapted to detect a power down state of core module 110 and/or glue logic domains 152-153 by monitoring operation of IU 120 and/or RL 130 (e.g., the inputs and/or outputs of buses 116 and/or 136) and detecting a particular logic state on buses 116 and/or 136 (e.g., a null logic state), or detecting an unchanging logic state, for example, for a pre-determined period of time (e.g., multiple bus clock cycles). Such substantially static logic states may indicate a corresponding power down state for core module 110 and/or external glue logic domains 152-153, and can indicate that monitored glue logic domain 151 may be powered down without negatively impacting operation of IC 100. In various embodiments, power controller 140 may be adapted to monitor and detect such logic states over bus 141, as described herein.

At block 604, power controller 140 may clamp an output of glue logic in monitored glue logic domain 151, in response to detecting a power down state as described in block 602. For example, clamp logic 441 of FIG. 4 (e.g. of power controller 140 of FIG. 1) may be adapted to provide a logic state to clamp cell 471 of IU/RL 420 over bus 441 corresponding to bus 141 of FIG. 1 and clamp outputs of IU/RL 420 to a particular logic state. In some embodiments, clamp logic 441 and clamp cell 471 may be adapted to store a current logic state of IU/RL 420 prior to clamping its outputs. The outputs may be clamped to the stored logic state, for example, or to a known logic state (e.g., a null logic state) prior to and/or while monitored glue logic domain 151 is powered down (e.g., substantially while power controller 140 detects a power down state as described in block 602). In other embodiments, clamp logic 441 and clamp cell 471 may be adapted to clamp outputs of IU/RL 420 without first storing their current logic state.

At block 606, power controller 140 may decouple IU 120 and/or RL 130 from power rail 103, in response to detecting a power down state as described in block 602. For example, as shown in FIG. 2, power controller 240 (analogous to power controller 140 in FIG. 1) may be adapted to decouple IU 220 and RL 230 from power rail 203 by providing a control signal to head switch 261 that turns head switch 261 “off” and decouples power rail 203 from intra-domain power rail 205.

At block 608, power controller 140 may detect a power up state of core module 151 and/or external glue logic domains 152-153. For example, power controller 140 may be adapted to detect a power up state of core module 110 and/or glue logic domains 152-153 by monitoring operation of IU 120 and/or RL 130 (e.g., the inputs and/or outputs of buses 116 and/or 136) and detecting a change in a logic state on buses 116 and/or 136 (e.g., from a null logic state), or detecting a changing logic state, for example, over a pre-determined period of time (e.g., multiple bus clock cycles). Such substantially changing logic states may indicate a corresponding power up state for core module 110 and/or external glue logic domains 152-153, and can indicate that monitored glue logic domain 151 may be powered up without wasting or dissipating power unnecessarily in IC 100. In other embodiments, power controller 140 may be adapted to detect or receive a power up signal over bus 141 from core module 110 to power up glue logic domain 151. In some embodiments, core module 110 may determine that it is ready to enter a power-on state. Prior to, while, or after entering the power-on state, core module 110 may provide a power up signal to glue logic domain 151 over bus 116 (e.g., to IU 120), which may then be provided to power controller 140 over bus 141. In other embodiments, where bus 141 couples core module 110 directly to power controller 140, the power up signal may be provided directly to power controller 140 over bus 141.

At block 610, power controller 140 of may couple IU 120 and/or RL 130 to power rail 103, in response to detecting a power up state as described in block 608. For example, as shown in FIG. 2, power controller 240 (analogous to power controller 140 in FIG. 1) may be adapted to couple IU 220 and RL 230 to power rail 203 by providing a control signal to head switch 261 that turns head switch 261 “on” and decouples power rail 203 to intra-domain power rail 205.

At block 612, power controller 140 may de-clamp an output of glue logic in glue logic domain 151, in response to detecting a power up state as described in block 608. For example, clamp logic 441 of FIG. 4 (e.g. analogous to power controller 140 of FIG. 1) may be adapted to de-clamp outputs of IU/RL 420 and/or provide a previously stored logic state to clamp cell 471 of IU/RL 420, as described herein. Once de-clamped, the outputs of IU/RL 420 may then operate as dictated by operation of IU/RL 420 (e.g., normal operation).

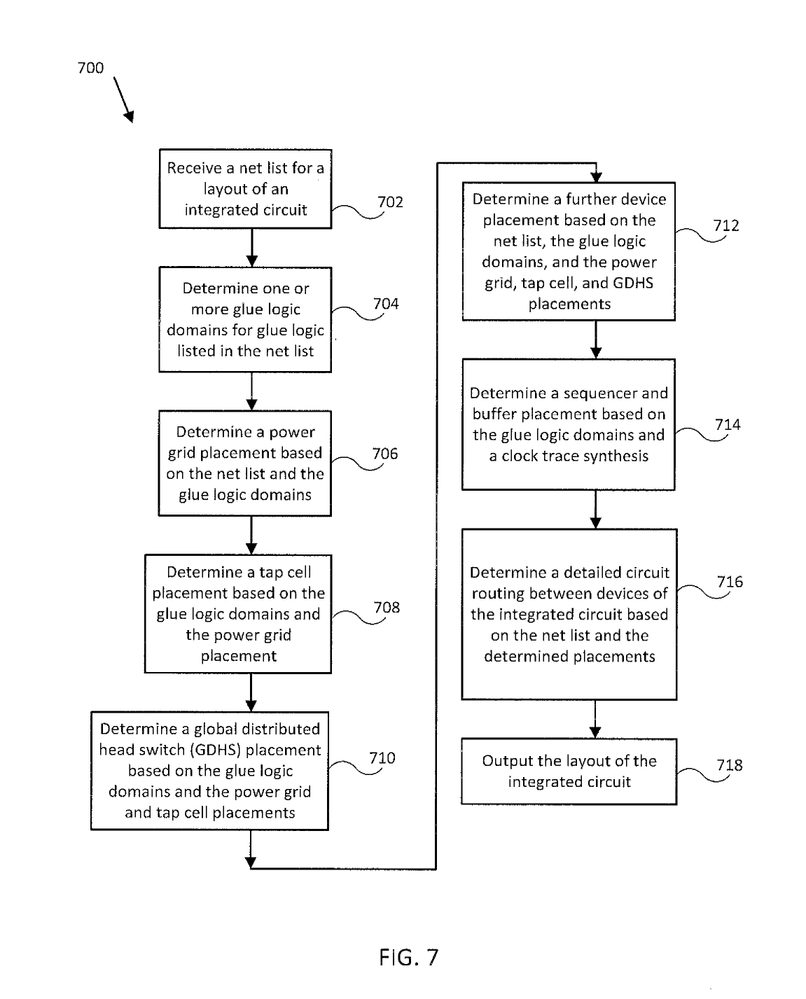

Methods to control power to glue logic domains may provide higher power efficiencies when used in conjunction with a layout of hard macro core modules and soft macro glue logic in an IC that prioritizes effective arrangement of glue logic into delineated glue logic domains. For example, FIG. 7 is a flowchart illustrating a method for determining a layout for an IC comprising collapsible glue logic in accordance with embodiments of the disclosure. In some embodiments, an IC design system may be adapted to determine one or more glue logic domains by determining which glue logic elements can be commonly powered without substantially negatively impacting operation of other portions of an IC or systems of ICs. The glue logic domains can be used to help determine power grid and device placement by spatially grouping glue logic elements and their power needs, which in turn can help determine circuit routing between the devices and between the power grid and the devices. Once the power grid, device placement, and circuit routing is complete, the IC design system may output a corresponding layout. In some embodiments, flowchart 700 may be performed by an IC design system executing computer readable code implementing the process embodied by flowchart 700. Such computer readable code may be implemented as a computer program product. An IC system may include a processor and memory, and, in some embodiments, be coupled to and adapted to control a semiconductor fabrication system. Any block, step or sub-step of flowchart 700 may be performed in an order or arrangement different from the specific embodiment illustrated by FIG. 7, and may include fewer, additional, or different steps, in accordance with the embodiments described herein.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. For example, such variations may include multiple hierarchical layers of core modules and glue logic domains controlled by corresponding power controllers, where higher-order layers may control the power states of lower-order layers, including power controllers implemented in lower-order layers. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. An electronic device comprising:
a plurality of hard macro core modules, each core module configured to be independently collapsible into a power-off state;
a plurality of soft macro glue logic domains corresponding to the plurality of core modules, wherein each glue logic domain is adapted to interface its corresponding core module to remaining ones of the core modules; and
a power controller adapted to control a power state for each glue logic domain, wherein the power controller is adapted to command a power-off state for each glue logic domain corresponding to a core module in the power off state.

2. The electronic device of claim 1, wherein each glue logic domain includes a power switch configured to couple the glue logic domain to a power supply, and wherein the power controller is configured to control the power switch for each glue logic domain to control the power state for each glue logic domain.

3. The electronic device of claim 2, wherein the power controller is adapted to:
receive a power down signal from the core modules in the power-off state; and
decouple the corresponding glue logic domains from the power supply using the corresponding power switches.

4. The electronic device of claim 2, wherein the power controller is adapted to:
detect the power-off state of the core modules in the power-off state; and
decouple the corresponding glue logic domains from the power supply using the corresponding power switches.

5. The electronic device of claim 2, wherein the power controller is adapted to:
detect a power-off state of one or more external glue logic domains that are decoupled from the power supply and that are associated with a monitored glue logic domain; and
decouple the monitored glue logic domain from the power supply using the corresponding power switch.

6. The electronic device of claim 1, wherein each glue logic domain includes at least one clamp cell configured to clamp outputs of the glue logic domain, and wherein the power controller is adapted to control the clamp cells to clamp outputs of the glue logic domains corresponding to the core modules in the power off state to one or more static logic states prior to decoupling power from the glue logic domains.

7. The electronic device of claim 1, wherein each core module includes a physical separation structure disposed along a boundary of the core module.

8. The electronic device of claim 1, wherein each glue logic domain is contained within a corresponding footprint on a substrate, and wherein devices within each glue logic domain are coupled together through at least one metal trace that extends outside of the corresponding footprint for the glue logic domain.

9. A method for controlling power to glue logic disposed within a glue logic domain, the method comprising:
receiving a power down signal to power down the glue logic domain;
clamping one or more outputs of the glue logic disposed within the glue logic domain; and
decoupling the glue logic from a power source for the glue logic domain.

10. The method of claim 9, wherein the glue logic domain includes a power switch configured to couple the glue logic domain to a power supply, and wherein the decoupling the glue logic comprises controlling the power switch to decouple the glue logic from the power source.

11. The method of claim 9, wherein the glue logic domain includes at least one clamp cell configured to clamp outputs of the glue logic domain, and wherein the clamping the one or more outputs comprises controlling the at least one clamp cell to clamp the one or more outputs to one or more static logic states prior to the decoupling the glue logic from the power source.

12. The method of claim 9, wherein:
the power down signal is provided by a core module implemented as a hard macro that includes a physical separation structure disposed along a boundary of the core module;
the glue logic domain comprises an interface unit or a routing logic module implemented as one or more soft macros; and
the interface unit or routing logic module comprises metal traces extending beyond a footprint of the interface unit or routing logic.

13. The method of claim 9, further comprising:
receiving a power up signal to power up the glue logic domain;
de-clamping the one or more outputs of the glue logic disposed within the glue logic domain; and
coupling the glue logic to the power source for the glue logic domain.

14. A method for controlling power to glue logic disposed within a monitored glue logic domain, the method comprising:
detecting a power down state of a core module or an external glue logic domain associated with the monitored glue logic domain;
clamping one or more outputs of the glue logic disposed within the monitored glue logic domain; and
decoupling the glue logic from a power source for the monitored glue logic domain.

15. The method of claim 14, wherein the monitored glue logic domain includes a power switch configured to couple the glue logic domain to a power supply, and wherein the decoupling the glue logic comprises controlling the power switch to decouple the glue logic from the power source.

16. The method of claim 14, wherein the monitored glue logic domain includes at least one clamp cell configured to clamp outputs of the monitored glue logic domain, and wherein the clamping the one or more outputs comprises controlling the at least one clamp cell to clamp the one or more outputs to one or more static logic states prior to the decoupling the glue logic from the power source.

17. The method of claim 9, wherein:
the power down signal is provided by a core module implemented as a hard macro that includes a physical separation structure disposed along a boundary of the core module;
the monitored glue logic domain comprises an interface unit or a routing logic module implemented as one or more soft macros; and
the interface unit or routing logic module comprises metal traces extending beyond a footprint of the interface unit or routing logic.

18. The method of claim 14, further comprising:
detecting a power up state of the core module;
de-clamping the one or more outputs of the glue logic disposed within the monitored glue logic domain; and
coupling the glue logic to the power source for the monitored glue logic domain.

19. The method of claim 14, further comprising:
detecting a power up state of the external glue logic domain;
de-clamping the one or more outputs of the glue logic disposed within the monitored glue logic domain; and
coupling the glue logic to the power source for the monitored glue logic domain.

20. The method of claim 14, further comprising:
receiving a power up signal to power up the monitored glue logic domain;
de-clamping the one or more outputs of the glue logic disposed within the monitored glue logic domain; and
coupling the glue logic to the power source for the monitored glue logic domain.
